(19) United States
(12) Patent Application Publication
(10) Pub. No.: US 2019/0181828 A1
(43) Pub. Date: Jun. 13, 2019

(54) ELECTRONIC COMPONENT MODULE

(71) Applicant: Murata Manufacturing Co., Ltd., Nagaokakyo-shi (JP)

(72) Inventor: Hideki IWAMOTO, Nagaokakyo-shi (JP)

(73) Assignee: Murata Manufacturing Co., Ltd., Nagaokakyo-shi, Kyoto-fu (JP)

(21) Appl. No.: 16/199,278

(22) Filed: Nov. 26, 2018

(30) Foreign Application Priority Data
Dec. 12, 2017 (JP) 2017-237540
Oct. 11, 2018 (JP) 2018-192317

(51) Int. Cl. H03H 9/02; H01L 41/053; H01L 41/047; H03H 9/25; H03H 9/145; H03H 9/05

(52) U.S. Cl. CPC H03H 9/02897; H01L 41/053; H01L 41/0475; H01L 41/29; H03H 9/145; H03H 9/058; H03H 9/02543; H03H 9/25

(57) ABSTRACT

An electronic component module includes a piezoelectric film on a support substrate defined by a crystal substrate. An insulation layer is provided on the support substrate. A wiring electrode is electrically connected to an IDT electrode, and at least a portion of the wiring electrode is provided on the insulation layer. An external connection electrode is electrically connected to the wiring electrode. The external connection electrode and the piezoelectric film do not overlap each other in a plan view in a thickness direction of the support substrate. An elastic wave device is mounted on a mounting substrate via the external connection electrode. The mounting substrate has a coefficient of linear expansion different from that of the support substrate. A surface on the piezoelectric film side of the support substrate is a {100} plane.

### CROSS REFERENCE TO RELATED APPLICATIONS

This application claims the benefit of priority to Japanese Patent Application No. 2017-237540 filed on Dec. 12, 2017 and Japanese Patent Application No. 2018-192317 filed on Oct. 11, 2018. The entire contents of these applications are hereby incorporated herein by reference.

### BACKGROUND OF THE INVENTION

### 1. Field of the Invention

The present invention relates to electronic component modules, and more particularly, to an electronic component module including an elastic wave device and a mounting substrate on which the elastic wave device is mounted.

### 2. Description of the Related Art

An elastic wave device in which a lamination film including a piezoelectric thin film is laminated on a support substrate is known (see, for example, Japanese Unexamined Patent Application Publication No. 2017-011681).

The elastic wave device disclosed in Japanese Unexamined Patent Application Publication No. 2017-011681 includes a support substrate, a piezoelectric film, such as a piezoelectric thin film, an interdigital transducer (IDT) electrode, an insulation layer, a wiring electrode, a spacer layer such as a support layer, a cover, a penetration electrode, such as an under bump metal layer, and an external connection electrode, such as a metal bump.

Japanese Unexamined Patent Application Publication No. 2017-011681 describes that cracking, chipping, or the like is unlikely to occur in the piezoelectric film during a process of forming the external connection electrode.

In the elastic wave device disclosed in Japanese Unexamined Patent Application Publication No. 2017-011681, there is an advantage that cracking, chipping, or the like is unlikely to occur in the piezoelectric film during the process of forming the external connection electrode. However, in an electronic component module in which the above-discussed elastic wave device is mounted on a mounting substrate, since a coefficient of linear expansion of the support substrate and a coefficient of linear expansion of the mounting substrate often differ from each other, there is a problem that a crack is generated in the support substrate in some case.

### SUMMARY OF THE INVENTION

Preferred embodiments of the present invention provide electronic component modules capable of reducing or preventing cracks, chips, or other damage in a piezoelectric film and reducing or preventing the occurrence of cracking in a support substrate.

An electronic component module according to a preferred embodiment of the present invention includes an elastic wave device and a mounting substrate. The elastic wave device is mounted on the mounting substrate. The elastic wave device includes a support substrate, a piezoelectric film, an interdigital transducer (IDT) electrode, an insulation layer, a wiring electrode, and an external connection electrode. The support substrate is a crystal substrate. The piezoelectric film is provided directly or indirectly on the support substrate. The IDT electrode is provided on the piezoelectric film. The insulation layer is provided on the support substrate. At least a portion of the wiring electrode is provided on the insulation layer. The wiring electrode is electrically connected to the IDT electrode. The external connection electrode is electrically connected to the wiring electrode. The external connection electrode and the piezoelectric film do not overlap each other in a plan view in a thickness direction of the support substrate. The elastic wave device is mounted on the mounting substrate via the external connection electrode. The mounting substrate has a coefficient of linear expansion different from a coefficient of linear expansion of the support substrate. A surface on the piezoelectric film side of the support substrate is a {100} plane.

An electronic component module according to a preferred embodiment of the present invention includes an elastic wave device and a mounting substrate. The elastic wave device is mounted on the mounting substrate. The mounting substrate is a printed wiring substrate or an LTCC substrate. The elastic wave device includes a support substrate, a piezoelectric film, an IDT electrode, an insulation layer, a wiring electrode, and an external connection electrode. The piezoelectric film is provided directly or indirectly on the support substrate. The IDT electrode is provided on the piezoelectric film. The insulation layer is provided on the support substrate. At least a portion of the wiring electrode is provided on the insulation layer. The wiring electrode is electrically connected to the IDT electrode. The external connection electrode is electrically connected to the wiring electrode. The external connection electrode and the piezoelectric film do not overlap each other in a plan view in a thickness direction of the support substrate. The elastic wave device is mounted on the mounting substrate via the external connection electrode. The support substrate is a silicon substrate, a germanium substrate, or a diamond substrate. A surface on the piezoelectric film side of the support substrate is a {100} plane.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a cross-sectional view of an electronic component module according to a first preferred embodiment of the present invention.

FIG. 2 is a plan view of an elastic wave device in the electronic component module, in which a cover is omitted.

FIG. 3 is a schematic diagram for explaining a crystal plane of silicon.

FIG. 4 is a cross-sectional view of an electronic component module according to a second preferred embodiment of the present invention.

FIG. 5 is a cross-sectional view of an electronic component module according to a third preferred embodiment of the present invention.

FIG. 6 is a cross-sectional view of an electronic component module according to a fourth preferred embodiment of the present invention.

FIG. 7 is a cross-sectional view of an electronic component module according to a fifth preferred embodiment of the present invention.

### DETAILED DESCRIPTION OF THE PREFERRED EMBODIMENTS

Hereinafter, electronic component modules according to preferred embodiments will be described with reference to the accompanying drawings.

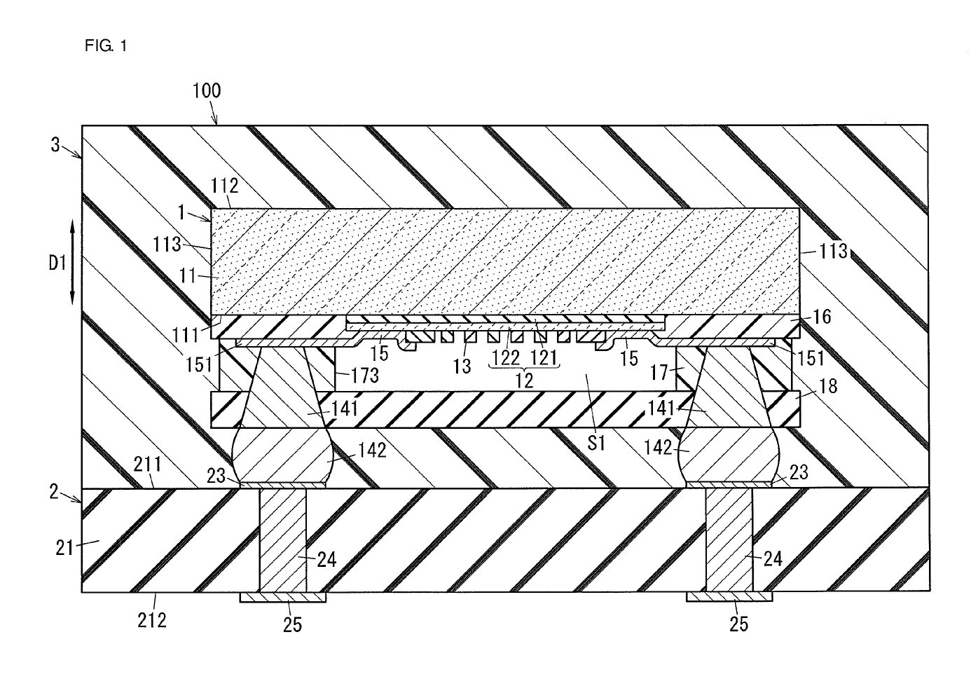

Note that FIGS. 1 to 7 are schematic drawings, and therefore the ratio of size, thickness, or other dimensions of each element in the drawings does not necessarily indicate the actual ratio of size, thickness, or other dimensions of the element.

### First Preferred Embodiment

Hereinafter, an electronic component module 100 according to a first preferred embodiment of the present invention will be described with reference to the drawings.

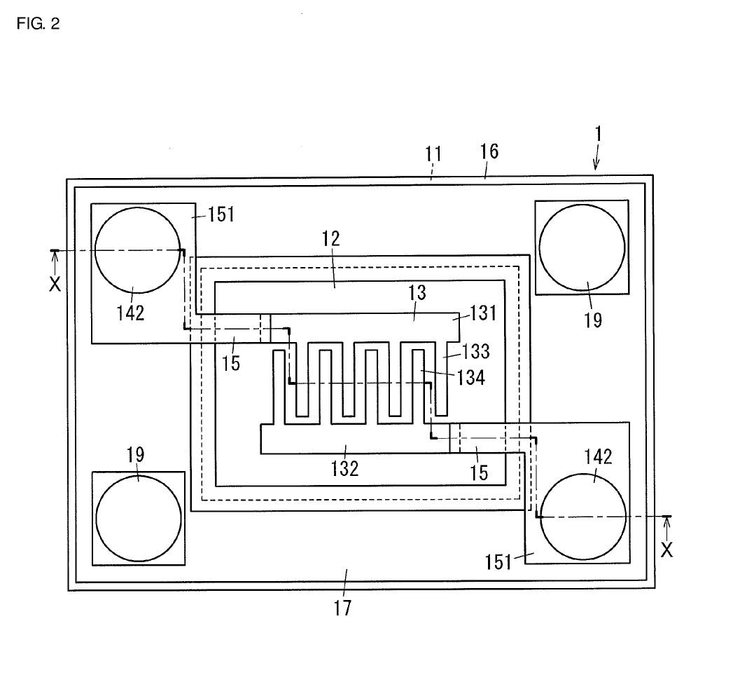

As illustrated in FIG. 1 and FIG. 2, the electronic component module 100 according to the first preferred embodiment includes an elastic wave device 1 and a mounting substrate 2. The elastic wave device 1 is mounted on the mounting substrate 2. FIG. 1, in which the elastic wave device 1 is illustrated, is a cross-sectional view corresponding to a cross section taken along a line X-X in FIG. 2. In FIG. 2, a cover 18 (see FIG. 1), which will be described later, is not illustrated.

The elastic wave device 1 includes a support substrate 11, a piezoelectric film 122, an interdigital transducer (IDT) electrode 13, an insulation layer 16, a wiring electrode 15, and a plurality of (two) external connection electrodes 142. The piezoelectric film 122 is provided on the support substrate 11. Here, in the elastic wave device 1, the piezoelectric film 122 is indirectly provided on the support substrate 11. The IDT electrode 13 is provided on the piezoelectric film 122. The phrase “provided on the piezoelectric film 122” means a case of being directly provided on the piezoelectric film 122 and a case of being indirectly provided on the piezoelectric film 122. The insulation layer 16 is provided on the support substrate 11. Here, the phrase “provided on the support substrate 11” means a case of being directly provided on the support substrate 11 and a case of being indirectly provided on the support substrate 11. The wiring electrode 15 is electrically connected to the IDT electrode 13, and at least a portion of the wiring electrode 15 is provided on the insulation layer 16. Here, the phrase “provided on the insulation layer 16” means a case of being directly provided on the insulation layer 16 and a case of being indirectly provided on the insulation layer 16. The external connection electrode 142 is electrically connected to the wiring electrode 15. The external connection electrode 142 and the piezoelectric film 122 do not overlap each other in a plan view in a thickness direction of the support substrate 11. The external connection electrode 142 is electrically connected to the wiring electrode 15. The elastic wave device 1 is mounted on the mounting substrate 2 via the external connection electrode 142. The elastic wave device 1 includes a functional film 12 including at least the piezoelectric film 122 and provided on the support substrate 11 between the support substrate 11 and the IDT electrode 13.

In addition, the elastic wave device 1 further includes a spacer layer 17 and the cover 18. At least a portion of the spacer layer 17 is provided on the insulation layer 16. Here, the phrase “provided on the insulation layer 16” means a case of being directly provided on the insulation layer 16 and a case of being indirectly provided on the insulation layer 16. The spacer layer 17 is provided in an outer side portion of the IDT electrode 13 in a plan view in the thickness direction of the support substrate 11. The spacer layer 17 includes a through-hole 173. The cover 18 is provided on the spacer layer 17. Here, the phrase “provided on the spacer layer 17” means a case of being directly provided on the spacer layer 17 and a case of being indirectly provided on the spacer layer 17. The cover 18 is provided on the spacer layer 17 and closes the through-hole 173 of the spacer layer 17.

In the electronic component module 100, the elastic wave device 1 is electrically and mechanically connected to the mounting substrate 2. In the electronic component module 100, a coefficient of linear expansion of the support substrate 11 is different from that of the mounting substrate 2. In other words, the mounting substrate 2 has a coefficient of linear expansion different from that of the support substrate 11.

In addition, the electronic component module 100 according to the first preferred embodiment further includes a protective layer 3 to protect the elastic wave device 1.

Next, elements of the elastic wave device 1 will be described with reference to the drawings.

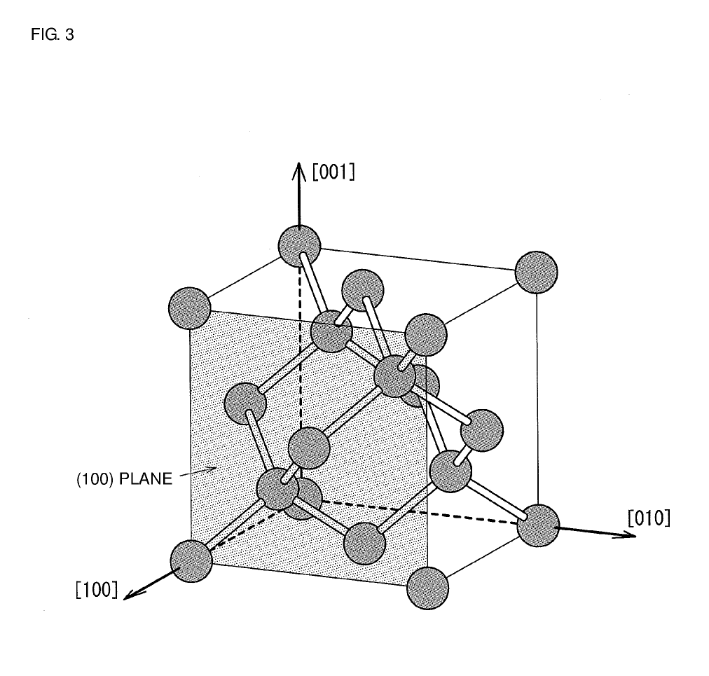

As illustrated in FIG. 1, the support substrate 11 supports a multilayer body including the piezoelectric film 122 and the IDT electrode 13. The support substrate 11 includes a first main surface 111 and a second main surface 112 on the opposite sides to each other in a thickness direction D1 thereof. The first main surface 111 and the second main surface 112 are back to back with each other. Although a shape in a plan view of the support substrate 11 (an outer circumferential shape of the support substrate 11 when viewed from the thickness direction D1) is preferably rectangular or substantially rectangular, the support substrate 11 is not limited to a rectangular substantially rectangular shape and may have, for example, a square or substantially square shape. The support substrate 11 is preferably a crystal substrate, for example. Specifically, the support substrate 11 is preferably a crystal substrate having a cubic crystal structure, for example. As an example, the support substrate 11 is a silicon substrate. A surface on the piezoelectric film 122 side (the first main surface 111) of the support substrate 11 is a (100) plane. The (100) plane is orthogonal or substantially orthogonal to a crystal axis of [100] in the crystal structure of silicon having a diamond structure as illustrated in FIG. 3. In FIG. 3, eighteen spheres are silicon atoms. The phrase “the first main surface 111 of the support substrate 11 is a (100) plane” means that the first main surface 111 of the support substrate 11 includes not only the (100) plane but also a crystal plane with an off angle from the (100) plane being greater than about 0 degrees and equal to or smaller than about five degrees. In the silicon substrate, since the (100) plane, a (001) plane, and a (010) plane are crystal planes equivalent to each other, the phrase “a surface on the piezoelectric film 122 side (the first main surface 111) of the support substrate 11 is a (100) plane” means that the first main surface 111 on the piezoelectric film 122 side of the support substrate 11 is a {100} plane. The support substrate 11 defines a high acoustic velocity support substrate in which bulk waves propagate at a higher acoustic velocity than an acoustic velocity of elastic waves propagating in the piezoelectric film 122. As a crystal substrate having a crystal structure, the support substrate 11 may preferably be made of, for example, a germanium substrate, a diamond substrate, or other suitable substrate, in addition to the silicon substrate. Therefore, the material of the support substrate 11 is not limited to silicon, and may be germanium, diamond, or other suitable material, for example.

The IDT electrode 13 may be made of an appropriate metal material, such as, for example, aluminum (Al), copper (Cu), platinum (Pt), gold (Au), silver (Ag), titanium (Ti), nickel (Ni), chromium (Cr), molybdenum (Mo), tungsten (W) or an alloy containing any one of these metals as a main ingredient. Further, the IDT electrode 13 may have a structure in which a plurality of metal films made of the above metals or alloys are laminated.

As illustrated in FIG. 2, the IDT electrode 13 includes a pair of busbars 131 and 132 (hereinafter, also referred to as a first busbar 131 and a second busbar 132), a plurality of electrode fingers 133 (hereinafter, also referred to as first electrode fingers 133) and a plurality of electrode fingers 134 (hereinafter, also referred to as second electrode fingers 134).

The first busbar 131 and the second busbar 132 each have an elongated shape denoting one direction (second direction) orthogonal or substantially orthogonal to the thickness direction D1 of the support substrate 11 (first direction) as a longitudinal direction thereof. In the IDT electrode 13, the first busbar 131 and the second busbar 132 oppose each other in a third direction orthogonal or substantially orthogonal to both the thickness direction D1 of the support substrate 11 (first direction) and the second direction.

The plurality of first electrode fingers 133 are connected to the first busbar 131 and extend toward the second busbar 132. Here, the plurality of first electrode fingers 133 extend, from the first busbar 131, along a direction (third direction) orthogonal or substantially orthogonal to the longitudinal direction (second direction) of the first busbar 131. The leading ends of the plurality of first electrode fingers 133 and the second busbar 132 are separate from each other. For example, each of the plurality of first electrode fingers 133 preferably has the same or substantially the same length and the same or substantially the same width.

The plurality of second electrode fingers 134 are connected to the second busbar 132 and extend toward the first busbar 131. Here, the plurality of second electrode fingers 134 extend, from the second busbar 132, along a direction orthogonal or substantially orthogonal to the longitudinal direction of the second busbar 132. Each leading end of the plurality of second electrode fingers 134 is separate from the first busbar 131. For example, each of the plurality of second electrode fingers 134 preferably has the same or substantially the same length and the same or substantially the same width. In the example in FIG. 2, the length and width of each of the plurality of second electrode fingers 134 are the same or substantially the same as the length and width of each of the plurality of first electrode fingers 133.

In the IDT electrode 13, the plurality of first electrode fingers 133 and the plurality of second electrode fingers 134 are alternately aligned, one by one, separate from each other in a direction orthogonal or substantially orthogonal to an opposing direction in which the first busbar 131 and the second busbar 132 oppose each other. Accordingly, the first electrode finger 133 and the second electrode finger 134 adjacent to each other in the longitudinal direction of the first busbar 131 are separated from each other. An electrode finger period of the IDT electrode 13 refers to a distance between the sides corresponding to each other of the first electrode finger 133 and the second electrode finger 134 adjacent to each other. A group of electrode fingers including the plurality of first electrode fingers 133 and the plurality of second electrode fingers 134 are only required to have a configuration in which the plurality of first electrode fingers 133 and the plurality of second electrode fingers 134 are aligned separate from each other in the second direction, and may have a configuration in which the plurality of first electrode fingers 133 and the plurality of second electrode fingers 134 are not alternately aligned separate from each other. For example, a region in which the first electrode fingers 133 and the second electrode fingers 134 are alternately aligned, one by one, separate from each other, and a region in which two of the first electrode fingers 133 or the second electrode fingers 134 are aligned in the second direction may be mixed.

The functional film 12 includes a low acoustic velocity film 121 in which bulk waves propagate at a lower acoustic velocity than an acoustic velocity of the elastic waves propagating in the piezoelectric film 122 and the piezoelectric film 122 directly or indirectly laminated on the low acoustic velocity film 121. The piezoelectric film 122 is indirectly laminated on the support substrate 11 defining a high acoustic velocity support substrate. In this case, the low acoustic velocity film 121 is between the support substrate 11 defining the high acoustic velocity support substrate and the piezoelectric film 122, thus decreasing the acoustic velocity of the elastic waves. Energy of elastic waves is intrinsically concentrated in a medium of low acoustic velocity. Due to this, the elastic wave device 1 improves an effect of confining the elastic wave energy into the piezoelectric film 122 and the IDT electrode 13 in which the elastic waves are excited. Therefore, the elastic wave device 1 is able to reduce loss and increase a Q value as compared with a case in which the low acoustic velocity film 121 is not provided. The functional film 12 may include, for example, a close contact layer interposed between the low acoustic velocity film 121 and the piezoelectric film 122 as another film other than the low acoustic velocity film 121 and the piezoelectric film 122. With this structure, it is possible to improve the adhesion between the low acoustic velocity film 121 and the piezoelectric film 122. The close contact layer is preferably made of, for example, resin (epoxy resin, polyimide resin, or other suitable resin), metal, or other suitable material. Further, the functional film 12 may include, but not limited to the close contact layer, a dielectric film at any one of the following positions: a position between the low acoustic velocity film 121 and the piezoelectric film 122, a position on the piezoelectric film 122, and a position under the low acoustic velocity film 121.

The piezoelectric film 122 is preferably made of, for example, any one of lithium tantalate (LiTaO₃), lithium niobate

(LiNbO₃), zinc oxide (ZnO), aluminum nitride (AlN) or lead zirconate titanate (PZT).

The low acoustic velocity film 121 is preferably made of, for example, any one of silicon oxide, glass, silicon oxynitride, tantalum oxide, a compound in which fluorine, carbon or boron is added to silicon oxide or a material including any one of the above materials as a main ingredient.

In the case in which the low acoustic velocity film is made of silicon oxide, it is possible to improve the temperature characteristics. The elastic coefficient of lithium tantalate has negative temperature characteristics, while the elastic coefficient of silicon oxide has positive temperature characteristics. Accordingly, in the elastic wave device 1, the absolute value of the temperature coefficient of frequency (TCF) is able to be made small. In addition, the specific acoustic impedance of silicon oxide is smaller than the specific acoustic impedance of lithium tantalate. Therefore, in the elastic wave device 1, both an increase in the electromechanical coupling coefficient, in other words, an expansion of the fractional bandwidth, and an improvement in the temperature coefficient of frequency is able to be achieved.

It is preferable that the film thickness of the piezoelectric film 122 is equal to or less than about 3.5λ, for example, where λ is a wave length of the elastic wave determined by the electrode finger period of the IDT electrode 13. This is because the Q value becomes high. Further, by setting the film thickness of the piezoelectric film 122 to be equal to or less than about 2.5λ, for example, the temperature coefficient of frequency is improved. Further, by setting the film thickness of the piezoelectric film 122 to be equal to or less than about 1.5λ, for example, the acoustic velocity is easily adjusted.

It is preferable that the film thickness of the low acoustic velocity film 121 is equal to or less than about 2.0λ, for example, where λ is a wave length of the elastic wave determined by the electrode finger period of the IDT electrode 13. By setting the film thickness of the low acoustic velocity film 121 to be equal to or less than about 2.0λ, for example, the film stress is able to be reduced, and as a result, warpage of a wafer including a silicon wafer defining a base member of the support substrate 11 at the time of manufacturing is able to be reduced, thus making it possible to improve the non-defective product ratio and stabilize the characteristics.

The wiring electrode 15 electrically connects the external connection electrode 142 and the IDT electrode 13. The wiring electrode 15 may preferably be made of, for example, an appropriate metal material such as aluminum, copper, platinum, gold, silver, titanium, nickel, chromium, molybdenum, tungsten or an alloy containing any one of these metals as a main ingredient. Further, the wiring electrode 15 may include a plurality of metal films made of these metals or alloys is layered.

The wiring electrode 15 overlaps a portion of the IDT electrode 13, a portion of the piezoelectric film 122, and a portion of the insulation layer 16 in the thickness direction of the support substrate 11. The external connection electrode 142 is provided on a section 151 of the wiring electrode 15 on the insulation layer 16. The wiring electrode 15 is positioned inside the outer circumference of the insulation layer 16 in a plan view.

The insulation layer 16 has an electrically insulative property. As illustrated in FIGS. 1 and 2, the insulation layer 16 is provided along the outer circumference of the support substrate 11 on the first main surface 111 of the support substrate 11. The insulation layer 16 surrounds the side surface of the piezoelectric film 122. Here, in the elastic wave device 1, the insulation layer 16 surrounds the side surface of the functional film 12. The insulation layer 16 preferably has a frame shape or a substantial frame shape (for example, a rectangular or substantially rectangular frame shape) in a plan view. A portion of the insulation layer 16 overlaps with an outer circumference portion of the piezoelectric film 122 in the thickness direction D1 of the support substrate 11. Here, in the elastic wave device 1, the above portion of the insulation layer 16 overlaps with an outer circumference portion of the functional film 12 in the thickness direction D1 of the support substrate 11. The side surface of the piezoelectric film 122 is covered with the insulation layer 16. Here, the side surface of the functional film 12 is covered with the insulation layer 16.

The material of the insulation layer 16 is preferably, for example, synthetic resin, such as epoxy resin or polyimide. A difference between the coefficient of linear expansion of the insulation layer 16 and the coefficient of linear expansion of the support substrate 11 is larger than a difference between the coefficient of linear expansion of the piezoelectric film 122 and the coefficient of linear expansion of the support substrate 11.

The spacer layer 17 includes the through-hole 173. The spacer layer 17 is provided in an outer side portion of the IDT electrode 13 and surrounds the IDT electrode 13, in a plan view in the thickness direction of the support substrate 11. The spacer layer 17 is provided along the outer circumference of the support substrate 11 in a plan view in the thickness direction of the support substrate 11. The spacer layer 17 preferably has a frame shape or a substantially frame shape in a plan view. The outer circumferential shape and the inner circumferential shape of the spacer layer 17 are preferably, for example, rectangular or substantially rectangular. The spacer layer 17 overlaps the insulation layer 16 in the thickness direction D1 of the support substrate 11. The outer circumferential shape of the spacer layer is smaller than the outer circumferential shape of the insulation layer 16. The inner circumferential shape of the spacer layer 17 is larger than the inner circumferential shape of the insulation layer 16. A portion of the spacer layer 17 also covers the wiring electrode 15 on a surface of the insulation layer 16. The spacer layer 17 includes a first section directly provided on the surface of the insulation layer 16, and a second section indirectly provided on the surface of the insulation layer 16 with the wiring electrode 15 interposed therebetween. Here, the first section is provided along the entire or substantially the entire circumference of the surface of the insulation layer 16.

The spacer layer 17 has an electrically insulative property. The material of the spacer layer 17 is preferably, for example, synthetic resin, such as epoxy resin or polyimide. It is preferable that the main ingredient of the material of the spacer layer 17 and the main ingredient of the material of the insulation layer 16 be the same, and it is more preferable that the material of the spacer layer 17 and the material of the insulation layer 16 be the same.

A total thickness of the thickness of the spacer layer 17 and the thickness of the insulation layer 16 is larger than a total thickness of the thickness of the functional layer 12 and the thickness of the IDT electrode 13.

The cover 18 preferably has a flat or substantially flat plate shape, for example. Although the shape of the cover 18 in a plan view (an outer circumferential shape when viewed from the thickness direction D1 of the support substrate 11) is rectangular or substantially rectangular, the shape is not limited to a rectangle and may be, for example, square or substantially square. The outer circumferential shape of the cover 18 has the same or substantially the same size as the outer circumferential shape of the support substrate 11. The cover 18 is disposed on the spacer layer 17 so as to close the through-hole 173 of the spacer layer 17. The cover 18 is separated from the IDT electrode 13 in the thickness direction D1. In the elastic wave device 1, the cover 18 has an electrically insulative property. The material of the cover 18 is preferably, for example, synthetic resin, such as epoxy resin or polyimide. It is preferable that the main ingredient of the material of the cover 18 and the main ingredient of the material of the spacer layer 17 be the same, and it is more preferable that the material of the cover 18 and the material of the spacer layer 17 be the same.

The elastic wave device 1 includes a space S1 surrounded by the cover 18, the spacer layer 17, the insulation layer 16, and the multilayer body (the multilayer body including the piezoelectric film 122 and the IDT electrode 13) on the support substrate 11. In the elastic wave device 1, gas is contained in the space S1. The gas is preferably, for example, air, an inert gas (e.g., a nitrogen gas) or other suitable gas.

The elastic wave device 1 includes a plurality of (two or more) external connection electrodes 142. The external connection electrode 142 is to be electrically connected with the mounting substrate 2 in the elastic wave device 1. In addition, the elastic wave device 1 may include a plurality of (two) mounting electrodes 19, which are not electrically connected to the IDT electrode 13 in some case. The mounting electrode 19 improves the parallelism of the elastic wave device 1 with respect to the mounting substrate 2, and is different from the electrode that provides electrical connection. In other words, the mounting electrode 19 prevents a situation in which the elastic wave device 1 is mounted and is inclined with respect to the mounting substrate 2, and is not absolutely necessary depending on the number and arrangement of the external connection electrodes 142, the outer circumferential shape of the elastic wave device 1, and other factors.

In the elastic wave device 1, in a plan view in the thickness direction D1 of the support substrate 11, two external connection electrodes 142 are respectively disposed in two of the four corners of the cover 18 diagonally opposing each other, and two mounting electrodes 19 are respectively disposed in the remaining two corners of the four corners. In the elastic wave device 1, in a plan view in the thickness direction D1 of the support substrate 11, none of the two external connection electrodes 142 and two mounting electrodes 19 overlap with the piezoelectric film 122.

The elastic wave device 1 includes a penetration electrode 141 penetrating through the spacer layer 17 and the cover 18 in the thickness direction D1 of the support substrate 11. The penetration electrode 141 is provided on the wiring electrode 15, and is electrically connected to the wiring electrode 15. The penetration electrode 141 defines an under bump metal layer. Further, the external connection electrode 142 is provided on the penetration electrode 141. The external connection electrode 142 is preferably, for example, a bump. The external connection electrode 142 has conductivity. The external connection electrode 142 is bonded to the penetration electrode 141, and is electrically connected to the penetration electrode 141. Further, the elastic wave device 1 includes a penetration electrode penetrating through the spacer layer 17 and the cover 18 in the thickness direction D1 of the support substrate 11 directly below the mounting electrode 19. The mounting electrode 19 is preferably, for example, a bump provided on the penetration electrode.

The penetration electrode 141 may be made of an appropriate metal material such as copper, nickel, or an alloy mainly containing any one of these metals, for example. The external connection electrode 142 may be made of, for example, solder, gold, copper, or other suitable material. The penetration electrode directly below the mounting electrode 19 is preferably made of the same material as that of the penetration electrode 141 directly below the external connection electrode 142. Further, the mounting electrode 19 is preferably made of the same material as that of the external connection electrode 142.

The elastic wave device 1 is mounted on the mounting substrate 2 via the external connection electrode 142. In the electronic component module 100, a single elastic wave device 1 is mounted on the mounting substrate 2. The mounting substrate 2 is larger in size than the elastic wave device 1 in a plan view in the thickness direction D1 of the support substrate 11.

The mounting substrate 2 includes a support body 21, a plurality of (two) first conductor sections 23 supported by the support body 21, and a plurality of (two) second conductor sections 25 supported by the support body 21. In addition, the mounting substrate 2 further includes a plurality of (two) penetration electrodes 24 electrically connecting the plurality of (two) first conductor sections 23 and the plurality of (two) second conductor sections 25 on a one-to-one basis. The second conductor section 25 is used to electrically connect the electronic component module 100 to a circuit board or other suitable substrate.

The support body 21 has an electrically insulative property. The support body 21 preferably has a flat or substantially flat plate shape and includes a first main surface 211 and a second main surface 212 that are positioned on the opposite sides to each other in a thickness direction thereof. The first main surface 211 and the second main surface 212 are back to back with each other. An outer circumferential shape of the support body 21 is preferably, for example, rectangular or substantially rectangular.

The first conductor section 23 is provided on the first main surface 211 of the support body 21. The first conductor section 23 is a conductive layer to which the external connection electrode 142 of the elastic wave device 1 is electrically connected. The material of the first conductor section 23 is preferably, for example, copper or other suitable material. The first conductor section 23 overlaps with the external connection electrode 142 in the thickness direction D1 of the support substrate 11 of the elastic wave device 1. The external connection electrode 142 is interposed between the penetration electrode 141 and the first conductor section 23. A conductive layer to which the mounting electrode 19 of the elastic wave device 1 is connected is also provided on the first main surface 211 of the support body 21. The conductive layer overlaps with the mounting electrode 19 in the thickness direction D1 of the support substrate 11 of the elastic wave device 1. The thickness of this conductive layer is preferably the same or substantially the same as that of the first conductor section 23. The material of this conductive layer is preferably the same or substantially the same as that of the first conductor section 23.

The second conductor section 25 is provided on the second main surface 212 of the support body 21. The first conductor section 23 is electrically connected to the second conductor section 25 via the penetration electrode 24. The material of the second conductor section 25 is preferably, for example, copper or other suitable material.

As an example, the mounting substrate 2 is preferably a printed wiring substrate. The coefficient of linear expansion of the printed wiring substrate is preferably, for example, about 15 ppm/° C. The printed wiring substrate is preferably made of, for example, a glass fabric epoxy resin copper-clad laminate.

The support body 21 is preferably an insulation substrate in the printed wiring substrate. The insulation substrate has an electrically insulative property.

The first conductor section 23 and the second conductor section 25 include copper foil of the printed wiring substrate.

In the electronic component module 100, the elastic wave device 1 mounted on the mounting substrate 2 is covered with the protective layer 3. In the electronic component module 100, the second main surface 112 and side surfaces 113 of the support substrate 11 of the elastic wave device 1 are covered with the protective layer 3. The material of the protective layer 3 is preferably, for example, synthetic resin, such as epoxy resin or polyimide. The protective layer 3 defines and functions as a sealing layer to seal the elastic wave device 1 on the mounting substrate 2. The protective layer 3 preferably has a rectangular or substantially rectangular parallelepiped shape, for example. A portion of the protective layer 3 is also provided around the external connection electrode 142 between the cover 18 of the elastic wave device 1 and the mounting substrate 2. In other words, a portion of the protective layer 3 defines an under-fill portion. The electronic component module 100 may be surface-mounted on a mother board or other substrate different from the mounting substrate 2. In the electronic component module 100, the mounting substrate 2 and the protective layer 3 define a package that protects the elastic wave device 1 and allows the connection with an external electric circuit or other circuit. The package in the electronic component module 100 is preferably a surface mount package, for example.

In a plan view in the thickness direction D1 of the support substrate 11, an outer circumferential shape of the protective layer 3 is preferably the same or substantially the same size as the outer circumferential shape of the mounting substrate 2.

Hereinafter, a non-limiting example of a manufacturing method for the elastic wave device 1 will be briefly described.

In the manufacturing method for the elastic wave device 1, a silicon wafer to be a base member of the support substrate 11 of each of a plurality of elastic wave devices 1 is prepared first.

In the manufacturing method for the elastic wave device 1, after the functional film 12 including the piezoelectric film 122 is formed on one main surface of the silicon wafer, the IDT electrode 13, the insulation layer 16, the wiring electrode 15, and the spacer layer 17 are sequentially formed; thereafter, the cover 18 is bonded to the spacer layer 17 to close the through-hole 173 of the spacer layer 17; subsequently, a through-hole is formed in a region of the cover 18 and the spacer layer 17 at which the penetration electrode 141 is expected to be formed, the penetration electrode 141 is formed to fill this through-hole, and then the external connection electrode 142 is formed on the penetration electrode 141. Thus, with the manufacturing method for the elastic wave device 1, a wafer in which the plurality of elastic wave devices 1 are formed on the silicon wafer is obtained. The one main surface of the silicon wafer corresponds to the first main surface 111 of the support substrate 11 defined by a silicon substrate.

In the manufacturing method for the elastic wave device 1, by performing a cutting process in which the wafer is cut with a dicing machine, the plurality of elastic wave devices 1 are obtained from a single wafer. In the cutting process, a dicing saw or other suitable device is preferably used, for example.

In a manufacturing method for the electronic component module 100, the elastic wave device 1 is mounted on the mounting substrate 2, and then the protective layer 3 is formed to cover the elastic wave device 1 on the mounting substrate 2. As a result, the electronic component module 100 is formed.

In an electronic component module 100 according to Working Example 1 of the first preferred embodiment, a support substrate 11 is a silicon substrate, and a first main surface 111 of the support substrate 11 is a (100) plane. The coefficient of linear expansion of the support substrate 11 is preferably about 4 ppm/° C., for example.

An electronic component module according to a comparative example has the same or substantially the same basic structure as that of the electronic component module 100 according to Working Example 1, and is different from the electronic component module 100 in that, in place of the support substrate 11 of the electronic component module 100 according to Working Example 1, a support substrate made of a silicon substrate whose first main surface is a (111) plane is provided.

Hereinafter, a result of performing a thermal shock test on both a sample of the electronic component module 100 according to Working Example 1 and a sample of the electronic component module according to the comparative example will be described. Here, the thermal shock test is a two-liquid tank temperature rapid change test conforming to JIS C 60068-2-14 and IEC 60068-2-14.

In the electronic component module 100 according to Working Example 1, preferably, for example, the material of a low acoustic velocity film 121 was silicon oxide, the material of a piezoelectric film 122 was lithium tantalate (LiTaO₃), the material of an IDT electrode 13 was aluminum (Al), the material of an insulation layer 16 was an epoxy resin, the material of a spacer layer 17 was an epoxy resin, the material of a cover 18 was an epoxy resin, the material of a penetration electrode 141 was copper (Cu), an external connection electrode 142 was defined by a bump, and the material of the bump was solder. Further, in the electronic component module 100 according to Working Example 1, preferably, for example, the thickness of the silicon substrate was set to about 125 μm, the thickness of the low acoustic velocity film 121 was set to about 600 nm, the thickness of the piezoelectric film 122 was set to about 600 nm, and the thickness of the IDT electrode 13 was set to about 150 nm. In the electronic component module 100 according to Working Example 1, preferably, for example, the coefficient of linear expansion of the support substrate 11 was about 4 ppm/° C., and the coefficient of linear expansion of a mounting substrate 2 was about 15 ppm/° C. Here, the coefficient of linear expansion of the mounting substrate 2 refers to a coefficient of linear expansion of an insulation substrate in a printed wiring substrate defining the mounting substrate 2 (a support body 21 in the mounting substrate 2).

In the electronic component module according to the comparative example, a crack, starting from a side surface of the support substrate and extending along the first main surface of the support substrate, was generated in the vicinity of the first main surface of the support substrate. In contrast, in the electronic component module 100 according to Working Example 1, no crack was generated in the support substrate 11.

In addition, in an electronic component module 100 according to Working Example 2, preferably, for example, a low temperature co-fired ceramics (LTCC) substrate, instead of the printed wiring substrate, was used as a mounting substrate 2. The coefficient of linear expansion of the mounting substrate 2 in this case was preferably about 10 ppm/° C., for example.

When a thermal shock test was performed on a sample of the electronic component module 100 according to Working Example 2 as one of reliability evaluations, no crack was generated in a support substrate 11 of the electronic component module 100 according to Working Example 2.

The electronic component module 100 according to the first preferred embodiment includes the elastic wave device 1 and the mounting substrate 2. The elastic wave device 1 is mounted on the mounting substrate 2. The elastic wave device 1 includes the support substrate 11, the piezoelectric film 122, the IDT electrode 13, the insulation layer 16, the wiring electrode 15, and the external connection electrode 142. The support substrate 11 is a crystal substrate. The piezoelectric film 122 is indirectly provided on the support substrate 11. The IDT electrode 13 is provided on the piezoelectric film 122. The insulation layer 16 is provided on the support substrate 11. At least a portion of the wiring electrode 15 is provided on the insulation layer 16. The wiring electrode 15 is electrically connected to the IDT electrode 13. The external connection electrode 142 and the piezoelectric film 122 do not overlap each other in a plan view in the thickness direction D1 of the support substrate 11. The elastic wave device 1 is mounted on the mounting substrate 2 via the external connection electrode 142. The mounting substrate 2 has a coefficient of linear expansion different from that of the support substrate 11. A surface on the piezoelectric film 122 side (the first main surface 111) of the support substrate 11 is a {100} plane.

In the electronic component module 100 according to the first preferred embodiment, since the external connection electrode 142 and the piezoelectric film 122 do not overlap each other in a plan view in the thickness direction of the support substrate 11, it is possible to prevent a situation in which force is applied from the external connection electrode 142 to the piezoelectric film 122 during the process of forming the external connection electrode 142 at the time of manufacturing, and thus it is possible to prevent the occurrence of cracking, chipping, or other damage in the piezoelectric film 122. In addition, in the electronic component module 100 according to the first preferred embodiment, since the coefficient of linear expansion of the support substrate 11 and that of the mounting substrate 2 are different from each other, thermal stress due to the difference in coefficient of linear expansion between the support substrate 11 and the mounting substrate 2 is applied to the support substrate 11. However, since the surface on the piezoelectric film 122 side (the first main surface 111) of the support substrate 11 is a {100} plane, even if the thermal stress due to the difference in coefficient of linear expansion between the support substrate 11 and the mounting substrate 2 is applied to the support substrate 11, it is possible to prevent the generation of a crack in the support substrate 11 because each of the side surfaces 113 of the support substrate 11 has a plane orientation unlikely to be separated by the generation of a crack (because the silicon atoms in the crystal structure of the support substrate 11 are arranged such that a portion of the support substrate 11 is unlikely to be separated by the generation of a crack) in comparison with a case in which the surface on the piezoelectric film 122 side (the first main surface 111) of the support substrate 11 is a (111) plane.

Note that, in the electronic component module 100 according to the first preferred embodiment, the piezoelectric film 122 (as well as the functional film 12 including the piezoelectric film 122) is not present at a position overlapping with the external connection electrode 142 in a plan view in the thickness direction D1 of the support substrate 11. Further, in a case in which a structure in which the piezoelectric film 122 (as well as the functional film 12 including the piezoelectric film 122) is present at the position overlapping with the external connection electrode 142 in a plan view in the thickness direction D1 of the support substrate 11 is taken as a comparative example, when a difference in coefficient of linear expansion between the insulation layer 16 and the support substrate 11 is greater than a difference in coefficient of linear expansion between the piezoelectric film 122 and the support substrate 11, a crack is more likely to be generated in the support substrate 11 in the electronic component module 100 than in the case of the comparative example.

The reason for this is as follows: in the case in which the insulation layer 16 is made of a material that causes a difference in coefficient of linear expansion between the insulation layer 16 and the support substrate 11 to be larger than a difference in coefficient of linear expansion between the piezoelectric film 122 and the support substrate 11, when a thermal shock is applied in the electronic component module 100, for example, as in a case of the thermal shock test being performed, not only the thermal stress due to the difference in coefficient of linear expansion between the support substrate 11 and the mounting substrate 2, but also the thermal stress due to the difference in coefficient of linear expansion between the support substrate 11 and the insulation layer 16 is applied to the support substrate 11. On the other hand, in the comparative example, when the thermal shock is applied, not only the thermal stress due to the difference in coefficient of linear expansion between the support substrate 11 and the mounting substrate 2, but also the thermal stress due to the difference in coefficient of linear expansion between the support substrate 11 and the piezoelectric film 122 is applied to the support substrate 11. However, since the thermal stress due to the difference in coefficient of linear expansion between the support substrate 11 and the piezoelectric film 122 is smaller than the thermal stress due to the difference in coefficient of linear expansion between the support substrate 11 and the insulation layer 16, cracking is more likely to occur in the support substrate 11 in the electronic component module 100 than in the case of the comparative example.

As described above, even in this case, in the electronic component module 100, since the surface on the piezoelectric film 122 side (the first main surface 111) is a (100) plane, as with the support substrate 11, it is possible to prevent the occurrence of cracking in the support substrate 11.

In addition, in the electronic component module 100 according to the first preferred embodiment, the mounting substrate 2 is a printed wiring substrate. With this, in the electronic component module 100, it is possible to reduce the cost as compared with a case where the mounting substrate 2 is formed of an LTCC substrate.

In addition, in the electronic component module 100 according to the first preferred embodiment, the piezoelectric film 122 (as well as the functional film 12 including the piezoelectric film 122) is provided inside the outer circumference of the support substrate 11 in a plan view in the thickness direction D1 of the support substrate 11. With this structure, in the electronic component module 100, it is possible to prevent a situation in which the piezoelectric film 122 (as well as the functional film 12 including the piezoelectric film 122) is separated from the support substrate 11 side during the cutting process with a dicing machine at the time of manufacturing, and thus, it is possible to improve the reliability.

Moreover, the electronic component module 100 according to the first preferred embodiment further includes the spacer layer 17, the cover 18, and the penetration electrode 141. At least a portion of the spacer layer 17 is provided on the insulation layer 16. The spacer layer 17 is provided in the outer side portion of the IDT electrode 13 in a plan view in the thickness direction D1 of the support substrate 11. The cover 18 is provided on the spacer layer 17. The penetration electrode 141 is provided on the insulation layer 16 and the wiring electrode 15. The penetration electrode 141 is electrically connected to the wiring electrode 15. The penetration electrode 141 penetrates through the spacer layer 17 and the cover 18. The external connection electrode 142 is electrically connected to the wiring electrode 15 and the penetration electrode 141. The external connection electrode 142 is provided on the penetration electrode 141 and the cover 18.

### Second Preferred Embodiment

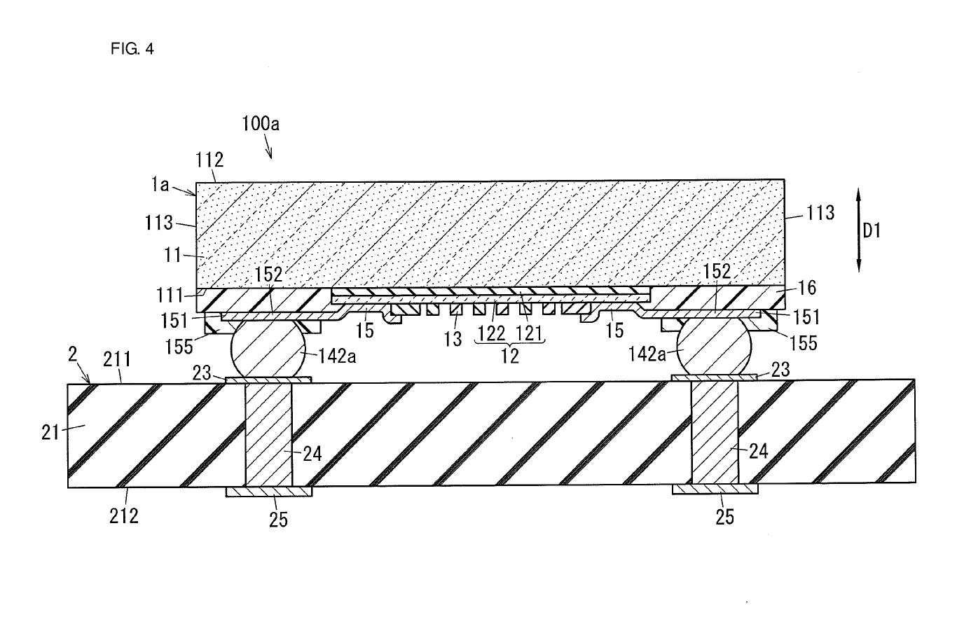

As illustrated in FIG. 4, an electronic component module 100a according to a second preferred embodiment of the present invention is different from the electronic component module 100 according to the first preferred embodiment in that an external connection electrode 142a is directly provided on a wiring electrode 15. Regarding the electronic component module 100a according to the second preferred embodiment, the same or similar elements as those of the electronic component module 100 according to the first preferred embodiment are denoted by the same reference numerals, and description thereof will be omitted.

In the electronic component module 100a according to the second preferred embodiment, an elastic wave device 1a does not include the spacer layer 17, the cover 18, and the penetration electrode 141, for example, provided in the elastic wave device 1 of the electronic component module 100 according to the first preferred embodiment. Further, in the electronic component module 100a, the external connection electrode 142a is directly provided on the wiring electrode 15. The external connection electrode 142a is preferably a bump. The material of the bump is preferably, for example, solder, Au, or other suitable material, for example.

The electronic component module 100a further includes a resist layer 155 covering a peripheral portion of a section 151 of the wiring electrode 15 provided on an insulation layer 16. In the electronic component module 100a, among the section 151 of the wiring electrode 15 provided on the insulation layer 16, a portion that is not covered with the resist layer 155 defines a pad electrode 152. The external connection electrode 142a is provided on the pad electrode 152 of the wiring electrode 15.

In the electronic component module 100a according to the second preferred embodiment, as in the electronic component module 100 according to the first preferred embodiment, since the external connection electrode 142a and a piezoelectric film 122 do not overlap each other (separate from each other) in a plan view in the thickness direction of a support substrate 11, it is possible to prevent a situation in which force from the external connection electrode 142a is applied to the piezoelectric film 122, and thus it is possible to prevent the occurrence of cracking in the piezoelectric film 122. In addition, since the electronic component module 100a according to the second preferred embodiment includes, as the electronic component module 100 according to the first preferred embodiment, a silicon substrate defining the support substrate 11 in which a surface on the piezoelectric film 122 side (first main surface 111) is a {100} plane, it is possible to prevent the occurrence of cracking in the support substrate 11 in comparison with a case of including a silicon substrate as the support substrate in which the surface on the piezoelectric film 122 side is a (111) plane.

In the electronic component module 100a according to the second preferred embodiment, the external connection electrode 142a is preferably a bump. The material of the bump is preferably solder or gold, for example. Thus, in the electronic component module 100a according to the second preferred embodiment, it is possible to simplify the configuration of the elastic wave device 1a as compared with the electronic component module 100 according to the first preferred embodiment.

The electronic component module 100a according to the second preferred embodiment may include a protective layer, similar to the protective layer 3 of the electronic component module 100 according to the first preferred embodiment, covering the elastic wave device 1a on the mounting substrate 2.

### Third Preferred Embodiment

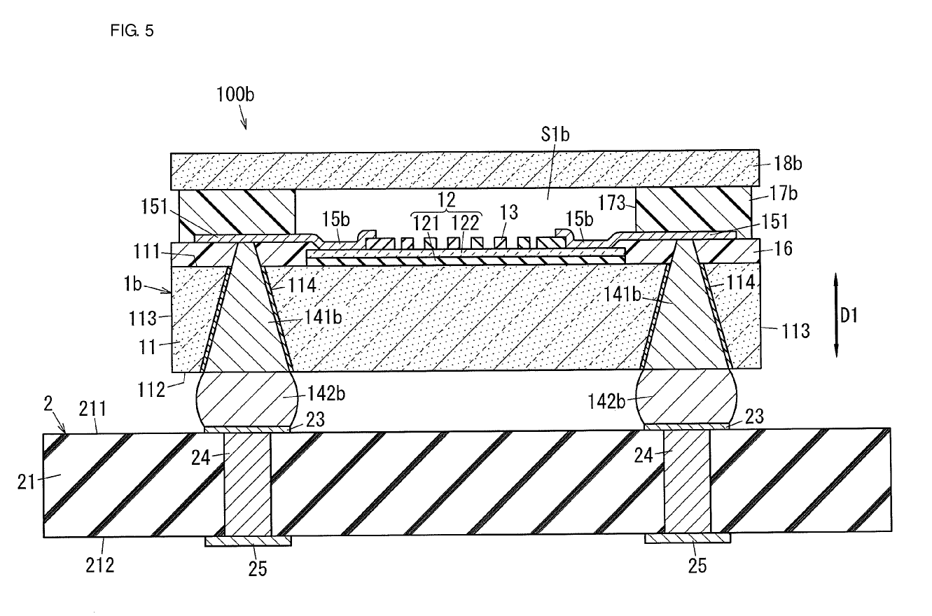

Hereinafter, an electronic component module 100b according to a third preferred embodiment of the present invention will be described with reference to FIG. 5.

The electronic component module 100b according to the third preferred embodiment is different from the electronic component module 100 according to the first preferred embodiment in that it includes, in place of the penetration electrode 141 and the external connection electrode 142 of the electronic component module 100 according to the first preferred embodiment, an external connection electrode 142b and a penetration electrode 141b penetrating through an insulation layer 16 and a support substrate 11. Regarding the electronic component module 100b according to the third preferred embodiment, the same or similar elements as those of the electronic component module 100 according to the first preferred embodiment will be denoted by the same reference numerals, and description thereof will be omitted.

The external connection electrode 142b overlaps with a section 151, among a wiring electrode 15, that is provided on the insulation layer 16, in a thickness direction D1 of the support substrate 11. The external connection electrode 142b is provided on the penetration electrode 141b penetrating through the insulation layer 16 and the support substrate 11 in the thickness direction D1 of the support substrate 11. An electrically insulative film 114 is interposed between the penetration electrode 141b and the support substrate 11. The electrically insulative film 114 is preferably made of, for example, silicon oxide. The penetration electrode 141b is electrically connected to a wiring electrode 15b. In short, the penetration electrode 141b is electrically connected to an IDT electrode 13 via the wiring electrode 15b. The wiring electrode 15b covers a portion of a piezoelectric film 122 and a portion of the IDT electrode 13. The penetration electrode 141b may preferably be made of an appropriate metal material, such as copper, nickel or an alloy mainly containing any one of these metals, for example. The external connection electrode 142b may preferably be made of, for example, solder, gold, copper or other suitable material.

The electronic component module 100b according to the third preferred embodiment includes a spacer layer 17b and a cover 18b, instead of the spacer layer 17 and the cover 18 of the electronic component module 100 according to the first preferred embodiment.

The spacer layer 17b is provided on the support substrate 11. More specifically, the spacer layer 17b is provided directly on a first main surface 111 of the support substrate 11 without the insulation layer 16 (see FIG. 1) interposed therebetween. The spacer layer 17b includes a through-hole 173. The material of the spacer layer 17b is preferably, for example, synthetic resin, such as epoxy resin or polyimide.

The thickness of the spacer layer 17b is greater than a total thickness of the thickness of a functional film 12 and the thickness of the IDT electrode 13.

The cover 18b is provided on the spacer layer 17b to close the through-hole 173 of the spacer layer 17b. The cover 18b is separated from the IDT electrode 13 in the thickness direction D1 of the support substrate 11.

In the electronic component module 100b, a difference in coefficient of linear expansion between the cover 18b and the support substrate 11 is smaller than a difference in coefficient of linear expansion between a mounting substrate 2 and the support substrate 11. The material of the cover 18b is preferably silicon, for example. In other words, the cover 18b is preferably a silicon substrate. Accordingly, a difference in coefficient of linear expansion between the cover 18b and the mounting substrate 2 is the same or substantially the same as the difference in coefficient of linear expansion between the mounting substrate 2 and the support substrate 11. The cover 18b may include, in addition to the silicon substrate, a thin film, such as an insulation film laminated on the silicon substrate. In the electronic component module 100b, a surface of the cover 18b on the opposite side to a surface on the support substrate 11 side thereof is a {100} plane. The cover 18b is formed by cutting, with a dicing machine, a silicon wafer to be a base member of a plurality of covers 18b. The thickness of the cover 18b may be different from or may be the same as the thickness of the support substrate 11.

An elastic wave device 1b includes a space S1b surrounded by the cover 18b, the spacer layer 17b, and a multilayer body (a multilayer body including the piezoelectric film 122 and the IDT electrode 13) on the support substrate 11. In the elastic wave device 1b, gas is contained in the space S1b. The gas is preferably, for example, air, an inert gas (e.g., a nitrogen gas) or other suitable gas.

In the electronic component module 100b according to the third preferred embodiment, as in the electronic component module 100 according to the first preferred embodiment, the external connection electrode 142b and the piezoelectric film 122 do not overlap each other in a plan view in the thickness direction D1 of the support substrate 11. With this structure, in the electronic component module 100b according to the third preferred embodiment, it is possible to prevent a situation in which force from the external connection electrode 142b is applied to the piezoelectric film 122, and thus, it is possible to prevent the occurrence of cracking, chipping, or other damage in the piezoelectric film 122 during the process of forming the external connection electrode 142b at the time of manufacturing. In addition, in the electronic component module 100b according to the third preferred embodiment, as in the electronic component module 100 according to the first preferred embodiment, since a surface on the piezoelectric film 122 side (first main surface 111) of the support substrate 11 is a {100} plane, it is possible to prevent the occurrence of cracking in the support substrate 11 in comparison with a case in which the surface on the piezoelectric film 122 side of the support substrate 11 is a (111) plane.

Moreover, in the electronic component module 100b, the difference in coefficient of linear expansion between the cover 18b and the support substrate 11 is smaller than the difference in coefficient of linear expansion between the mounting substrate 2 and the support substrate 11. Thus, in the electronic component module 100b, it is possible to further prevent the occurrence of cracking in the support substrate 11.

In the electronic component module 100b, the material of the cover 18b is preferably silicon, for example. With this structure, in the electronic component module 100b, it is possible to make the difference in coefficient of linear expansion between the cover 18b and the support substrate 11 be smaller, and thus it is possible to reduce the thermal stress applied from the cover 18b to the support substrate 11. Further, in the electronic component module 100b, since the penetration electrode 141b penetrates through the support substrate 11, it is possible to improve the heat dissipation property in comparison with a case in which the penetration electrode 141 penetrates through the spacer layer 17 made of resin and the cover 18 made of resin as in the case of the electronic component module 100 according to the first preferred embodiment. Furthermore, in the electronic component module 100b, since the material of the cover 18b is silicon, it is possible to improve the mold resistance at the time of molding with resin, for example.

In addition, in the electronic component module 100b, a surface of the cover 18b including the silicon substrate on the opposite side to a surface on the support substrate 11 side thereof is a {100} plane. As a result, in the electronic component module 100b, as compared with a case in which the surface of the cover 18b is a (111) plane in the cutting process with a dicing machine at the time of manufacturing, for example, the plane orientation is able to be aligned at the support substrate 11 and the cover 18b, and therefore, the occurrence of chipping in the cover 18b is able to be prevented.

### Fourth Preferred Embodiment

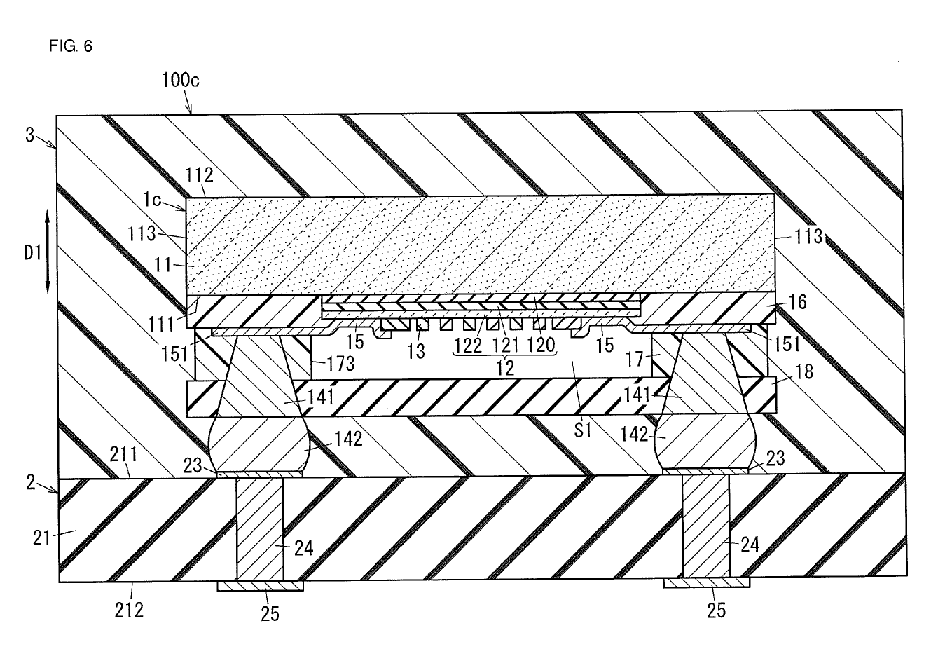

In an electronic component module 100c according to a fourth preferred embodiment of the present invention, as illustrated in FIG. 6, a functional film 12 in an elastic wave device 1c includes a high acoustic velocity film 120, a low acoustic velocity film 121, and a piezoelectric film 122. The high acoustic velocity film 120 is provided directly or indirectly on a support substrate 11. In the high acoustic velocity film 120, bulk waves propagate at a higher acoustic velocity than an acoustic velocity of elastic waves propagating in the piezoelectric film 122. The low acoustic velocity film 121 is provided directly or indirectly on the high acoustic velocity film 120. In the low acoustic velocity film 121, bulk waves propagate at a lower acoustic velocity than the acoustic velocity of the elastic waves propagating in the piezoelectric film 122. The piezoelectric film 122 is provided directly or indirectly on the low acoustic velocity film 121. Regarding the electronic component module 100c according to the fourth preferred embodiment, the same or similar elements as those of the electronic component module 100 according to the first preferred embodiment (see FIG. 1) will be denoted by the same reference numerals, and description thereof will be omitted.

In the elastic wave device 1c of the electronic component module 100c according to the fourth preferred embodiment, the high acoustic velocity film 120 functions so that elastic waves do not leak to a structure under the high acoustic velocity film 120.

With this structure, in the elastic wave device 1c, energy of elastic waves of a specific mode used to obtain the characteristics of a filter, a resonator or other device is distributed across the entirety or substantially the entirety of the piezoelectric film 122 and the low acoustic velocity film 121, also distributed across a portion of the high acoustic velocity film 120 on the low acoustic velocity film 121 side, and not distributed on the support substrate 11. A mechanism to confine the elastic waves by the high acoustic velocity film 120 is a mechanism similar to that for Love waves, which are non-leaky shear horizontal (SH) waves, and is described in, for example, “Introduction to Simulation Technologies for Surface Acoustic Wave Devices”, by Kenya Hashimoto, Realize Corp., pp. 26-28. The above-discussed mechanism is different from a mechanism to confine elastic waves by using a Bragg reflector with an acoustic multilayer film.

The high acoustic velocity film 120 is preferably made of, for example, diamond-like carbon, aluminum nitride, aluminum oxide, silicon carbide, silicon nitride, silicon, sapphire, lithium tantalate, lithium niobate, a piezoelectric material such as quartz, various ceramics such as alumina, zirconia, cordierite, mullite, steatite and forsterite, magnesia diamond, a material containing the above materials as a main ingredient or a material containing a mixture of the above materials as a main ingredient.

As for the film thickness of the high acoustic velocity film 120, since the high acoustic velocity film 120 confines elastic waves to the piezoelectric film 122 and the low acoustic velocity film 121, it is preferable that the film thickness of the high acoustic velocity film 120 is thicker. The functional film 12 may include, for example, a close contact layer or a dielectric film as another film other than the high acoustic velocity film 120, the low acoustic velocity film 121 and the piezoelectric film 122.

In the electronic component module 100c according to the fourth preferred embodiment, as in the electronic component module 100 according to the first preferred embodiment, an external connection electrode 142 and the piezoelectric film 122 do not overlap each other in a plan view in a thickness direction D1 of the support substrate 11. With this structure, in the electronic component module 100c according to the fourth preferred embodiment, it is possible to prevent a situation in which force from the external connection electrode 142 is applied to the piezoelectric film 122, and thus it is possible to prevent the occurrence of cracking, chipping, or other damage in the piezoelectric film 122 during the process of forming the external connection electrode 142 at the time of manufacturing. In addition, in the electronic component module 100c according to the fourth preferred embodiment, as in the electronic component module 100 according to the first preferred embodiment, since a surface on the piezoelectric film 122 side (first main surface 111) of the support substrate 11 is a {100} plane, it is possible to prevent the occurrence of cracking in the support substrate 11 in comparison with a case in which the surface on the piezoelectric film 122 side of the support substrate 11 is a (111) plane.

### Fifth Preferred Embodiment

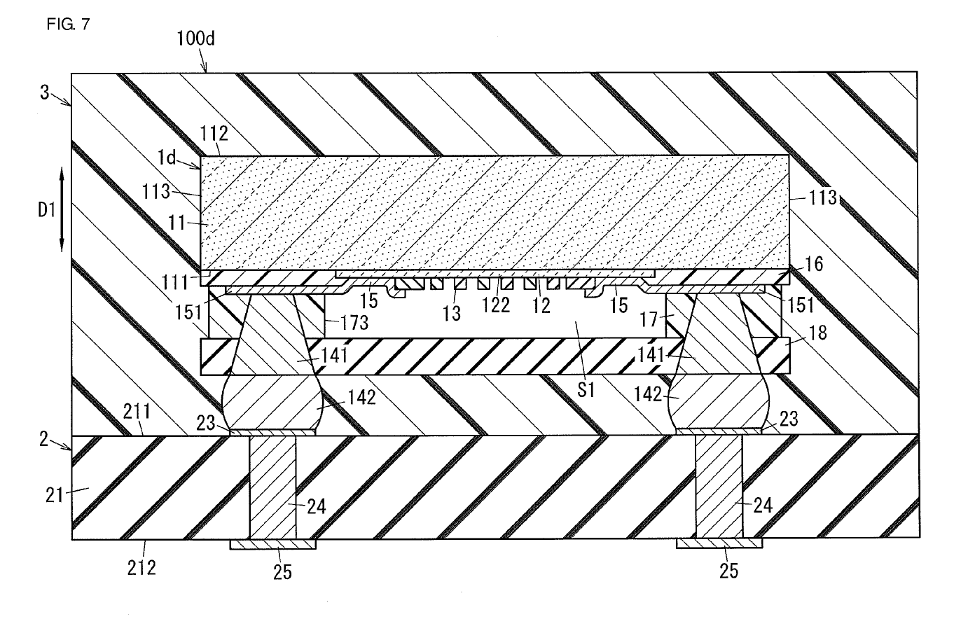

As illustrated in FIG. 7, in an electronic component module 100d according to a fifth preferred embodiment of the present invention, the functional film 12 in the elastic wave device 1c corresponds to a piezoelectric film 122. The piezoelectric film 122 is provided directly on a support substrate 11. Regarding the electronic component module 100d according to the fifth preferred embodiment, the same or similar elements as those of the electronic component module 100 according to the first preferred embodiment (see FIG. 1) will be denoted by the same reference numerals, and description thereof will be omitted.

The support substrate 11 defines a high acoustic velocity support substrate in which bulk waves propagate at a higher acoustic velocity than an acoustic velocity of elastic waves propagating in the piezoelectric film 122. The functional film 12 may preferably include, for example, as another film other than the piezoelectric film 122, a close contact layer or a dielectric film provided on the support substrate 11 side of the piezoelectric film 122. Further, the functional film 12 may include a dielectric film or other film provided on an IDT electrode 13 side of the piezoelectric film 122.

In the electronic component module 100d according to the fifth preferred embodiment, as in the electronic component module 100 according to the first preferred embodiment, an external connection electrode 142 and the piezoelectric film 122 do not overlap each other in a plan view in a thickness direction D1 of the support substrate 11. With this structure, in the electronic component module 100d according to the fifth preferred embodiment, it is possible to prevent a situation in which force from the external connection electrode 142 is applied to the piezoelectric film 122, and thus it is possible to prevent the occurrence of cracking, chipping, or other damage in the piezoelectric film 122, during the process of forming the external connection electrode 142 at the time of manufacturing. In addition, in the electronic component module 100d according to the fifth preferred embodiment, as in the electronic component module 100 according to the first preferred embodiment, since a surface on the piezoelectric film 122 side (first main surface 111) is a {100} plane as the support substrate 11, it is possible to prevent the occurrence of cracking in the support substrate 11 in comparison with a case in which the surface on the piezoelectric film 122 side is a (111) plane as the support substrate 11.

Each of the preferred embodiments described above is merely one of various preferred embodiments of the present invention. A variety of modifications may be made to the above-described preferred embodiments in accordance with design or the like as long as the advantageous effects of the present invention are achieved.

For example, the printed wiring substrate defining the mounting substrate 2 is not limited to being made of a glass fabric epoxy resin copper-clad laminate, and may be made of, for example, a glass fabric polyimide-based resin copper-clad laminate, a paper epoxy resin copper-clad laminate, a paper glass fabric epoxy resin copper-clad laminate, a glass nonwoven-fabric glass fabric epoxy resin copper-clad laminate, or other suitable materials.

Further, the mounting substrate 2 is not limited to a printed wiring substrate, and may be, for example, a low temperature co-fired ceramics (LTCC) substrate. The LTCC substrate is a substrate having been fired at equal to or lower than about 1000° C. (e.g., about 850° C. to about 1000° C.), which is relatively low in temperature as compared with the firing temperature of an alumina substrate. The coefficient of linear expansion of the LTCC substrate is, for example, about 10 ppm/° C.

Further, each of the electronic component modules 100, 100a, 100b, 100c and 100d is not limited to the configuration in which only the single elastic wave device 1, 1a, 1b, 1c or 1d is mounted as an electronic component on the mounting substrate 2, and may include a plurality of elastic wave devices 1, 1a, 1b, 1c or 1d that are mounted or the elastic wave device 1, 1a, 1b, 1c or 1d, and an electronic component other than the elastic wave devices 1, 1a, 1b, 1c and 1d may be mounted together, for example.

In addition, the functional film 12 may be provided with an acoustic impedance layer. The acoustic impedance layer is provided between the piezoelectric film 122 and the support substrate 11. The acoustic impedance layer prevents the leakage of elastic waves excited by the IDT electrode 13 to the support substrate 11. The acoustic impedance layer has a laminated structure in which at least one high acoustic impedance layer having a relatively high acoustic impedance and at least one low acoustic impedance layer having a relatively low acoustic impedance are aligned in the thickness direction D1 of the support substrate 11. In the above-described laminated structure, a plurality of high acoustic impedance layers may be provided, or a plurality of low acoustic impedance layers may be provided. In this case, the laminated structure includes a plurality of high acoustic impedance layers and a plurality of low acoustic impedance layers that are alternately aligned, one by one, in the thickness direction D1 of the support substrate 11.

The high acoustic impedance layer is preferably made of, for example, platinum, tungsten, aluminum nitride, lithium tantalate, sapphire, lithium niobate, silicon nitride or zinc oxide.

The low acoustic impedance layer is preferably made of, for example, silicon oxide, aluminum or titanium.

Although a single IDT electrode 13 is provided on the piezoelectric film 122 in the elastic wave devices 1, 1a, 1b, 1c and 1d, the number of IDT electrodes 13 is not limited to one, and a plurality of IDT electrodes 13 may be provided. In the case in which the elastic wave devices 1, 1a, 1b, 1c and 1d each include a plurality of IDT electrodes 13, for example, a plurality of surface acoustic wave resonators including the respective plurality of IDT electrodes 13 may be electrically connected to each other to define a band pass filter, for example.

Further, the material of the insulation layer 16 and the spacer layers 17 and 17b in the elastic wave devices 1, 1b, 1c and 1d is not limited to an organic material, such as synthetic resin, and may be an inorganic material.

In the electronic component module 100b, it is sufficient that a difference in coefficient of linear expansion between the cover 18b and the support substrate 11 is smaller than a difference in coefficient of linear expansion between the mounting substrate 2 and the support substrate 11, and the cover 18b is not limited to a silicon substrate, and may be, for example, a borosilicate glass substrate or other suitable substrate.

The following advantageous effects are disclosed based on the above-described preferred embodiments.

An electronic component module (100, 100a, 100b, 100c and 100d) according to a preferred embodiment of the present invention includes the elastic wave device (1, 1a, 1b, 1c or 1d) and the mounting substrate (2). Each of the elastic wave devices (1, 1a, 1b, 1c and 1d) is mounted on the mounting substrate (2). Each of the elastic wave devices (1, 1a, 1b, 1c and 1d) includes the support substrate (11), the piezoelectric film (122), the IDT electrode (13), the insulation layer (16), the wiring electrode (15 or 15b), and the external connection electrode (142, 142a or 142b). The support substrate (11) is a crystal substrate. The piezoelectric film (122) is provided directly or indirectly on the support substrate (11). The IDT electrode (13) is provided on the piezoelectric film (122). The insulation layer (16) is provided on the support substrate (11). At least a portion of each of the wiring electrodes (15 and 15b) is provided on the insulation layer (16). Each of the wiring electrodes (15 and 15b) is electrically connected to the IDT electrode (13). Each of the external connection electrodes (142, 142a and 142b) is electrically connected to the wiring electrode (15). Each of the external connection electrodes (142, 142a and 142b) and the piezoelectric film (122) do not overlap each other in a plan view in the thickness direction (D1) of the support substrate (11). Each of the elastic wave devices (1, 1a, 1b, 1c and 1d) is mounted on the mounting substrate (2) via the external connection electrode (142, 142a or 142b). The mounting substrate (2) has a coefficient of linear expansion different from that of the support substrate (11). A surface on the piezoelectric film (122) side (the first main surface 111) of the support substrate (11) is a {100} plane.

In the electronic component modules (100, 100a, 100b, 100c and 100d), it is possible to reduce or prevent the occurrence of cracking, chipping or other damage in the piezoelectric film (122) and the occurrence of cracking in the support substrate (11).

An electronic component module (100, 100a, 100b, 100c and 100d) according to a preferred embodiment of the present invention includes the elastic wave device (1, 1a, 1b, 1c or 1d) and the mounting substrate (2). Each of the elastic wave devices (1, 1a, 1b, 1c and 1d) is mounted on the mounting substrate (2). The mounting substrate (2) is a printed wiring substrate or an LTCC substrate. Each of the elastic wave devices (1, 1a, 1b, 1c and 1d) includes the support substrate (11), the piezoelectric film (122), the IDT electrode (13), the insulation layer (16), the wiring electrode (15 or 15b), and the external connection electrode (142, 142a or 142b). The piezoelectric film (122) is provided directly or indirectly on the support substrate (11). The IDT electrode (13) is provided on the piezoelectric film (122). The insulation layer (16) is provided on the support substrate (11). At least a portion of each of the wiring electrodes (15 and 15b) is provided on the insulation layer (16). Each of the wiring electrodes (15 and 15b) is electrically connected to the IDT electrode (13). Each of the external connection electrodes (142, 142a and 142b) is electrically connected to the wiring electrode (15). Each of the external connection electrodes (142, 142a and 142b) and the piezoelectric film (122) do not overlap each other in a plan view in the thickness direction (D1) of the support substrate (11). Each of the elastic wave devices (1, 1a, 1b, 1c and 1d) is mounted on the mounting substrate (2) via the external connection electrode (142, 142a or 142b). The support substrate (11) is a silicon substrate, a germanium substrate or a diamond substrate. A surface on the piezoelectric film (122) side (the first main surface 111) of the support substrate (11) is a {100} plane.

In the electronic component module (100, 100a, 100b, 100c and 100d), it is possible to prevent the occurrence of cracking, chipping, or other damage in the piezoelectric film (122) and the occurrence of cracking in the support substrate (11).

An electronic component module (100, 100a, 100b, 100c and 100d) according to a preferred embodiment of the present invention is structured such that a difference between a coefficient of linear expansion of the insulation layer (16) and that of the support substrate (11) is larger than a difference between a coefficient of linear expansion of the piezoelectric film (122) and that of the support substrate (11).

An electronic component module (100) according to a preferred embodiment of the present invention further includes the spacer layer (17), the cover (18), and the penetration electrode (141). The spacer layer (17) is provided on the insulation layer (16). The cover (18) is provided on the spacer layer (17). The penetration electrode (141) is provided on the insulation layer (16) and the wiring electrode (15). The penetration electrode (141) is electrically connected to the wiring electrode (15). The penetration electrode (141) penetrates through the spacer layer (17) and the cover (18) in the thickness direction (D1). The external connection electrode (142) is provided on the penetration electrode (141) and the cover (18). The external connection electrode (142) is electrically connected to the wiring electrode (15) and the penetration electrode (141).

An electronic component module (100b) according to a preferred embodiment of the present invention includes the spacer layer (17b), the cover (18b), and the penetration electrode (141b). At least a portion of the spacer layer (17b) is provided on the insulation layer (16). The spacer layer (17b) is provided in the outer side portion of the IDT electrode (13) in a plan view in the thickness direction (D1) of the support substrate (11). The cover (18b) is provided on the spacer layer (17b). The penetration electrode (141b) is electrically connected to the wiring electrode (15b). The penetration electrode (141b) penetrates through the insulation layer (16) and the support substrate (11). The external connection electrode (142b) is electrically connected to the penetration electrode (141b). The external connection electrode (142b) overlaps with the penetration electrode (141b) in a plan view in the thickness direction (D1) of the support substrate (11). The external connection electrode (142b) is provided on a side of the surface (second main surface 112) of the support substrate (11) on the opposite side to the surface (first main surface 111) on the piezoelectric film (122) side of the support substrate (11).

In an electronic component module (100b) according to a preferred embodiment of the present invention, since the penetration electrode (141b) penetrates through the support substrate (11), it is possible to improve the heat dissipation property as compared with a case in which the penetration electrode penetrates through the spacer layer made of resin and the cover made of resin.

An electronic component module (100, 100a, 100b, 100c and 100d) according to a preferred embodiment of the present invention is structured such that a difference in coefficient of linear expansion between the cover (18 or 18b) and the support substrate (11) is smaller than a difference in coefficient of linear expansion between the mounting substrate (2) and the support substrate (11).

In the electronic component module (100, 100a, 100b, 100c and 100d), it is possible to reduce or prevent the occurrence of cracking in the support substrate (11).

An electronic component module (100, 100a, 100b, 100c and 100d) according to a preferred embodiment of the present invention is structured such that the cover (18 or 18b) is made of silicon.

In the electronic component module (100, 100a, 100b, 100c and 100d), the difference in coefficient of linear expansion between the cover (18 or 18b) and the support substrate (11) is able to be made smaller.

An electronic component module (100, 100a, 100b, 100c and 100d) according to a preferred embodiment of the present invention is structured such that a surface of the cover (18 or 18b) on the opposite side to the surface on the support substrate (11) side thereof is a {100} plane.

In the electronic component modules (100, 100a, 100b, 100c and 100d) according to preferred embodiments of the present invention, it is possible to prevent the occurrence of chipping in the cover (18 or 18b) in comparison with a case in which the surface of the cover (18b) is a (111) plane in the cutting process with a dicing machine at the time of manufacturing, for example.

An electronic component module (100, 100a, 100b, 100c and 100d) according to a preferred embodiment of the present invention is structured such that the mounting substrate (2) is a printed wiring substrate.

In the electronic component module (100, 100a, 100b, 100c and 100d), there is an advantage that an inductor is able to be easily provided in the mounting substrate (2), for example, as compared with a case in which the mounting substrate (2) is an LTCC substrate.

An electronic component module (100, 100a, 100b, 100c and 100d) according to a preferred embodiment of the present invention is structured such that the external connection electrode (142, 142a or 142b) is a bump. The material of the bump is solder or gold, for example.

An electronic component module (100, 100a and 100b) according to preferred embodiments of the present invention is structured such that the elastic wave device (1, 1a or 1b) further includes the low acoustic velocity film (121). The low acoustic velocity film (121) is provided on the support substrate (11), and the acoustic velocity of the bulk waves propagating in the low acoustic velocity film (121) is lower than the acoustic velocity of the elastic waves propagating in the piezoelectric film (122). The support substrate (11) defines a high acoustic velocity support substrate in which the bulk waves propagate at an acoustic velocity higher than that of the elastic waves propagating in the piezoelectric film (122).

In the electronic component module (100, 100a and 100b) according to preferred embodiments of the present invention, it is possible to reduce the loss and increase the Q value in the elastic wave device (1, 1a or 1b) as compared with a case in which the low acoustic velocity film (121) is not provided.

An electronic component module (100c) according to a preferred embodiment of the present invention is configured such that the elastic wave device (1c) further includes the high acoustic velocity film (120) and the low acoustic velocity film (121). The high acoustic velocity film (120) is provided on the support substrate (11), and the acoustic velocity of the bulk waves propagating in the high acoustic velocity film (120) is higher than the acoustic velocity of the elastic waves propagating in the piezoelectric film (122). The low acoustic velocity film (121) is provided on the high acoustic velocity film (120), and the acoustic velocity of the bulk waves propagating in the low acoustic velocity film (121) is lower than the acoustic velocity of the elastic waves propagating in the piezoelectric film (122).

In the electronic component module (100c), it is possible to prevent the leakage of elastic waves into the support substrate (11).

An electronic component module (100, 100a, 100b, 100c and 100d) according to a preferred embodiment of the present invention is structured such that the material of the support substrate (11) is silicon, germanium or diamond.

An electronic component module (100, 100a, 100b, 100c and 100d) according to a preferred embodiment of the present invention is structured such that the material of the piezoelectric film (122) is lithium tantalate, lithium niobate, zinc oxide, aluminum nitride or PZT.

An electronic component module (100, 100a and 100b) according to a preferred embodiment of the present invention is structured such that the material of the low acoustic velocity film (121) is at least one kind of material selected from the group including silicon oxide, glass, silicon oxynitride, tantalum oxide, and a compound in which fluorine, carbon, or boron is added to silicon oxide.

An electronic component module (100c) according to a preferred embodiment of the present invention is structured such that the material of the high acoustic velocity film (120) is at least one kind of material selected from the group including diamond-like carbon, aluminum nitride, aluminum oxide, silicon carbide, silicon nitride, silicon, sapphire, lithium tantalate, lithium niobate, quartz, alumina, zirconia, cordierite, mullite, steatite, forsterite and magnesia diamond.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An electronic component module comprising:
an elastic wave device; and
a mounting substrate on which the elastic wave device is mounted; wherein
the elastic wave device includes:
a support substrate defined by a crystal substrate;
a piezoelectric film directly or indirectly on the support substrate;
an IDT electrode on the piezoelectric film;
an insulation layer on the support substrate;
a wiring electrode electrically connected to the IDT electrode, and at least a portion of which is provided on the insulation layer; and
an external connection electrode electrically connected to the wiring electrode;
the external connection electrode and the piezoelectric film do not overlap each other in a plan view in a thickness direction of the support substrate;
the elastic wave device is mounted on the mounting substrate via the external connection electrode;
the mounting substrate has a coefficient of linear expansion different from a coefficient of linear expansion of the support substrate; and
a surface on the piezoelectric film side of the support substrate is a {100} plane.

2. An electronic component module comprising:
an elastic wave device; and
a mounting substrate defined by a printed wiring substrate or an LTCC substrate, and on which the elastic wave device is mounted; wherein
the elastic wave device includes:
a support substrate;
a piezoelectric film directly or indirectly on the support substrate;
an IDT electrode on the piezoelectric film;
an insulation layer on the support substrate;
a wiring electrode electrically connected to the IDT electrode, and at least a portion of which is provided on the insulation layer; and
an external connection electrode electrically connected to the wiring electrode;
the external connection electrode and the piezoelectric film do not overlap each other in a plan view in a thickness direction of the support substrate;
the elastic wave device is mounted on the mounting substrate via the external connection electrode;
the support substrate is defined by a silicon substrate, a germanium substrate or a diamond substrate; and
a surface on the piezoelectric film side of the support substrate is a {100} plane.

3. The electronic component module according to claim 1, wherein a difference between a coefficient of linear expansion of the insulation layer and a coefficient of linear expansion of the support substrate is larger than a difference between a coefficient of linear expansion of the piezoelectric film and the coefficient of linear expansion of the support substrate.

4. The electronic component module according to claim 1, wherein
the elastic wave device further includes a spacer layer, a cover, and a penetration electrode;
the spacer layer is provided in an outer side portion of the IDT electrode in a plan view in the thickness direction of the support substrate, and at least a portion of the spacer layer is provided on the insulation layer;
the cover is provided on the spacer layer;
the penetration electrode is provided on the insulation layer and the wiring electrode, is electrically connected to the wiring electrode, and penetrates through the spacer layer and the cover; and
the external connection electrode is provided on the penetration electrode and the cover, and is electrically connected to the wiring electrode and the penetration electrode.

5. The electronic component module according to claim 1, wherein
the elastic wave device further includes a spacer layer, a cover, and a penetration electrode;
the spacer layer is provided in an outer side portion of the IDT electrode in a plan view in the thickness direction of the support substrate, and at least a portion of the spacer layer is provided on the insulation layer;
the cover is provided on the spacer layer;
the penetration electrode is electrically connected to the wiring electrode, and penetrates through the insulation layer and the support substrate; and
the external connection electrode is electrically connected to the penetration electrode, overlaps with the penetration electrode in a plan view in the thickness direction of the support substrate, and is provided on a surface of the support substrate on an opposite side to a surface on the piezoelectric film side of the support substrate.

6. The electronic component module according to claim 4, wherein a difference in coefficients of linear expansion between the cover and the support substrate is smaller than a difference in coefficients of linear expansion between the mounting substrate and the support substrate.

7. The electronic component module according to claim 4, wherein a material of the cover is silicon.

8. The electronic component module according to claim 7, wherein a surface of the cover on an opposite side to a surface on the support substrate side is a {100} plane.

9. The electronic component module according to claim 1, wherein the mounting substrate is a printed wiring substrate.

10. The electronic component module according to claim 1, wherein
the external connection electrode includes a bump; and
the material of the bump is solder or gold.

11. The electronic component module according to claim 1, wherein
the elastic wave device further includes a low acoustic velocity film provided on the support substrate between the support substrate and the piezoelectric film, and in which bulk waves propagate at an acoustic velocity lower than an acoustic velocity of elastic waves propagating in the piezoelectric film; and
the support substrate defines a high acoustic velocity support substrate in which bulk waves propagate at an acoustic velocity higher than the acoustic velocity of the elastic waves propagating in the piezoelectric film.

12. The electronic component module according to claim 1, wherein
the elastic wave device further includes:
a high acoustic velocity film on the support substrate between the support substrate and the piezoelectric film, and in which bulk waves propagate at an acoustic velocity higher than an acoustic velocity of elastic waves propagating in the piezoelectric film; and
a low acoustic velocity film on the high acoustic velocity film between the support substrate and the piezoelectric film, and in which bulk waves propagate at an acoustic velocity lower than the acoustic velocity of the elastic waves propagating in the piezoelectric film.

13. The electronic component module according to claim 1, wherein a material of the support substrate is silicon, germanium or diamond.

14. The electronic component module according to claim 1, wherein a material of the piezoelectric film is lithium tantalate, lithium niobate, zinc oxide, aluminum nitride or PZT.

15. The electronic component module according to claim 11, wherein a material of the low acoustic velocity film is at least one material selected from a group including silicon oxide, glass, silicon oxynitride, tantalum oxide and a compound in which fluorine, carbon or boron is added to silicon oxide.

16. The electronic component module according to claim 12, wherein a material of the high acoustic velocity film is at least one material selected from a group including diamond-like carbon, aluminum nitride, aluminum oxide, silicon carbide, silicon nitride, silicon, sapphire, lithium tantalate, lithium niobate, quartz, alumina, zirconia, cordierite, mullite, steatite, forsterite and magnesia diamond.

17. The electronic component module according to claim 2, wherein a difference between a coefficient of linear expansion of the insulation layer and a coefficient of linear expansion of the support substrate is larger than a difference between a coefficient of linear expansion of the piezoelectric film and the coefficient of linear expansion of the support substrate.

18. The electronic component module according to claim 2, wherein
the elastic wave device further includes a spacer layer, a cover, and a penetration electrode;
the spacer layer is provided in an outer side portion of the IDT electrode in a plan view in the thickness direction of the support substrate, and at least a portion of the spacer layer is provided on the insulation layer;
the cover is provided on the spacer layer;
the penetration electrode is provided on the insulation layer and the wiring electrode, is electrically connected to the wiring electrode, and penetrates through the spacer layer and the cover; and
the external connection electrode is provided on the penetration electrode and the cover, and is electrically connected to the wiring electrode and the penetration electrode.

19. The electronic component module according to claim 2, wherein
the elastic wave device further includes a spacer layer, a cover, and a penetration electrode;
the spacer layer is provided in an outer side portion of the IDT electrode in a plan view in the thickness direction of the support substrate, and at least a portion of the spacer layer is provided on the insulation layer;
the cover is provided on the spacer layer;
the penetration electrode is electrically connected to the wiring electrode, and penetrates through the insulation layer and the support substrate; and
the external connection electrode is electrically connected to the penetration electrode, overlaps with the penetration electrode in a plan view in the thickness direction of the support substrate, and is provided on a surface of the support substrate on an opposite side to a surface on the piezoelectric film side of the support substrate.

20. The electronic component module according to claim 18, wherein a difference in coefficients of linear expansion between the cover and the support substrate is smaller than a difference in coefficients of linear expansion between the mounting substrate and the support substrate.
